(19) United States
(12) Patent Application Publication
(10) Pub. No.: US 2026/0089991 A1
(43) Pub. Date: Mar. 26, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Tomokazu KANNA, Tokyo (JP); Tetsuya HIGASHI, Tokyo (JP); Koji TANAKA, Tokyo (JP); Reona FURUKAWA, Tokyo (JP); Takashi FUJIMOTO, Tokyo (JP); Kazuya KONISHI, Tokyo (JP)

(73) Assignee: Mitsubishi Electric Corporation, Tokyo (JP)

(21) Appl. No.: 19/269,914

(22) Filed: Jul. 15, 2025

(30) Foreign Application Priority Data
Sep. 26, 2024 (JP) 2024-167015

(51) Int. Cl. H10D 12/00; H10D 12/01; H10D 64/23

(52) U.S. Cl. CPC H10D 12/481; H10D 12/035; H10D 12/038; H10D 64/232

(57) ABSTRACT

A semiconductor device according to the present disclosure includes a first trench electrode and a second trench electrode, in which the first trench electrode has a two-stage structure including a lower electrode provided on a lower side that is a side of a second main electrode, an upper electrode provided on an upper side that is a side of a first main electrode, a first trench insulating film covering an inner surface of the trench, and a partition insulating film provided between the lower electrode and the upper electrode, the upper electrode has a recess in a portion corresponding to an upper side of the lower electrode, and a side wall of the recess serves as a pointed portion protruding toward a bottom portion of the trench, the partition insulating film is provided to cover an inside of the recess and the pointed portion.

### BACKGROUND OF THE INVENTION

### Field of the Invention

The present disclosure relates to a semiconductor device, and particularly to a semiconductor device including a trench electrode having a two-stage structure.

### Description of the Background Art

In recent years, as disclosed in FIG. 4 of Japanese Patent Application Laid-Open No. 2024-1723, a semiconductor device including a two-stage trench electrode having an upper trench electrode on an upper side and a lower trench electrode on a lower side in a thickness direction of a semiconductor substrate and a one-stage trench electrode having a one-stage trench electrode has been developed.

In Japanese Patent Application Laid-Open No. 2024-1723, not a gate potential but a source potential is applied to the lower electrode of the two-stage trench electrode, and the lower electrode functions as a field plate electrode. In addition, the source potential is applied to the trench electrode of the one-stage trench electrode.

In the semiconductor device as described above, the trench electrodes of all the lower electrodes and the one-stage trench electrode are connected to the source potential, and thus, there is a problem that collector-gate capacitance (Cgc) decreases, a ratio (Cgc/Cge) of Cgc to emitter-gate capacitance (Cge) decreases, and turn-on loss increases in a case where gate resistance of a semiconductor element is increased and a recovery dv/dt at the time of turn-on is set at a predetermined value.

### SUMMARY

The present disclosure relates to a semiconductor device, and an object of the present disclosure is to provide a semiconductor device including a trench electrode having a two-stage structure and capable of suppressing increase in turn-on loss and improving reliability.

A semiconductor device according to the present disclosure includes: a semiconductor substrate that includes at least a first semiconductor layer of a first conductivity type, a second semiconductor layer of a second conductivity type on the first semiconductor layer, and a third semiconductor layer of the first conductivity type provided in an upper layer portion of the second semiconductor layer; a first trench electrode and a second trench electrode provided inside a trench that penetrates the third semiconductor layer and the second semiconductor layer of the semiconductor substrate in a thickness direction and reaches an inside of the first semiconductor layer; an interlayer insulating film covering the first trench electrode and the second trench electrode; a first main electrode in contact with the third semiconductor layer; and a second main electrode provided on a side opposite to the first main electrode in the thickness direction of the semiconductor substrate, in which the first trench electrode has a two-stage structure including a lower electrode provided on a lower side that is a side of the second main electrode, an upper electrode provided on an upper side that is a side of the first main electrode, a first trench insulating film covering an inner surface of the trench, and a partition insulating film provided between the lower electrode and the upper electrode, in the upper electrode, a portion corresponding to an upper side of the lower electrode is as a recess, and a side wall of the recess is as a pointed portion protruding toward a bottom portion of the trench, the partition insulating film is provided to cover an inside of the recess and the pointed portion, the second trench electrode includes a second trench insulating film covering an inner surface of the trench, and a trench electrode with which the trench covered with the second trench insulating film is filled, and a viewing member embedded in an upper region of the second trench insulating film, the upper electrode is connected to a potential of the first main electrode, and the lower electrode and the trench electrode are connected to a gate potential.

According to the semiconductor device of the present disclosure, in the semiconductor device including a trench electrode having a two-stage structure, it is possible to obtain a semiconductor device capable of suppressing increase in turn-on loss and improving reliability.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an upper surface configuration of a semiconductor device of a first preferred embodiment according to the present disclosure;

FIG. 2 is a plan view of a partial region in an active region;

FIG. 3 is a cross-sectional view of the partial region in the active region;

FIG. 4 is a view illustrating a thicknesses of each portion in a two-stage trench electrode and a one-stage trench electrode;

FIGS. 5 to 18 are cross-sectional views illustrating a manufacturing process of the semiconductor device of the first preferred embodiment according to the present disclosure;

FIG. 19 is a cross-sectional view illustrating a configuration of a semiconductor device according to a first modification of the first preferred embodiment according to the present disclosure;

FIG. 20 is a plan view illustrating a configuration of a semiconductor device of a second preferred embodiment according to the present disclosure;

FIGS. 21 to 23 are cross-sectional views in an arrow direction of a partial region in an active region;

FIG. 24 is a cross-sectional view illustrating a configuration of a semiconductor device of a third preferred embodiment according to the present disclosure;

FIG. 25 is a cross-sectional view illustrating a configuration of a semiconductor device of a fourth preferred embodiment according to the present disclosure;

FIG. 26 is a plan view schematically illustrating an upper surface configuration of a semiconductor device of a fifth preferred embodiment according to the present disclosure;

FIG. 27 is a plan view of a partial region in an active region; and

FIG. 28 is a cross-sectional view of the partial region in the active region.

### DESCRIPTION OF THE PREFERRED EMBODIMENTS

### Introduction

Hereinafter, preferred embodiments according to the present disclosure will be described with reference to the accompanying drawings. Note that the drawings provide schematic illustrations, and a mutual relationship of sizes and positions of images illustrated in different drawings is not necessarily accurately described, and can be appropriately changed. Furthermore, in the following description, similar components are denoted by the same reference numerals, and names and functions thereof are also similar. Thus, detailed description thereof may be omitted.

Furthermore, in the following description, even if terms meaning specific positions or directions such as “upper”, “lower”, “side”, “bottom”, “front”, or “back” are used, these terms are used for convenience to facilitate understanding of the content of the preferred embodiments, and are not related to the directions when the preferred embodiments are actually implemented. In addition, in the following description, “outside” is a direction toward an outer periphery of the semiconductor device, and “inside” is a direction opposite to “outside”.

In the following description, an n-type is generally defined as a “first conductivity type” and a p-type is generally defined as a “second conductivity type” with respect to conductivity types of impurities, but the opposite definition may be used.

In addition, an n⁻ type indicates that impurity concentration is lower than that of the n-type, and an n⁺ type indicates that impurity concentration is higher than that of the n-type. Similarly, a p⁻ type indicates that impurity concentration is lower than that of the p-type, and a p⁺ type indicates that impurity concentration is higher than that of the p-type.

### First Preferred Embodiment

### <Device Configuration>

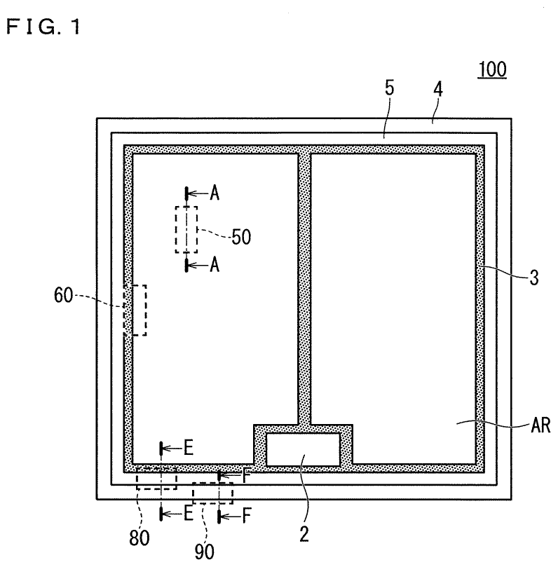

FIG. 1 is a plan view schematically illustrating an upper surface configuration of an entire insulated gate bipolar transistor (IGBT) 100 of a first preferred embodiment according to the present disclosure. The IGBT 100 illustrated in FIG. 1 has a quadrangular outer shape, and most of the outer shape is an active region AR in which a plurality of minimum unit structures of the IGBT (IGBT cells) called “unit cells” is arranged and a main current flows. The outside of the active region AR is a termination region 5. In the active region AR, a plurality of trench electrodes (not illustrated) is provided in parallel at intervals. Note that the plurality of trench electrodes is connected to a gate wiring 3 provided in the active region AR, and the gate wiring 3 is connected to a gate pad 2. A dicing line 4 is provided outside the termination region 5. Note that shapes and arrangement of the gate wiring 3 and the gate pad 2 are not limited to those in FIG. 1.

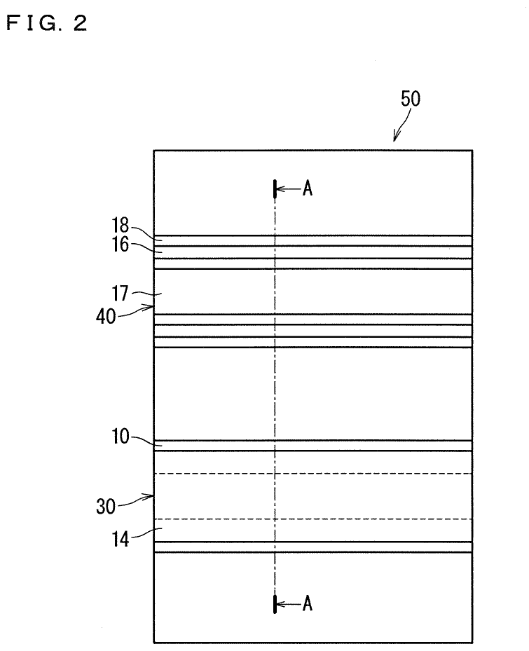

FIG. 2 illustrates a plan view of a partial region 50 surrounded by a dashed line in the active region AR of FIG. 1. FIG. 2 is a partial plan view in which an upper structure such as an emitter electrode in the active region AR is omitted.

As illustrated in FIG. 2, in the active region AR, a two-stage trench electrode 30 (first trench electrode) having a stripe shape and a one-stage trench electrode 40 (second trench electrode) are provided so that longitudinal directions thereof are parallel to each other. The two-stage trench electrode 30 and the one-stage trench electrode 40 are provided so as to extend in a direction (left-right direction on the paper) intersecting with an extending direction of the gate wiring 3 provided in a central portion of the active region AR. Note that the extending direction of the two-stage trench electrode 30 and the one-stage trench electrode 40 is not limited thereto, and a vertical direction on the paper may be the extending direction.

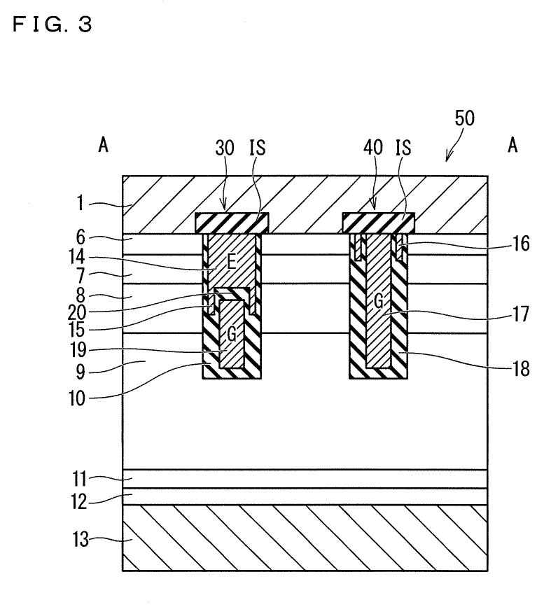

FIG. 3 is a cross-sectional view in an arrow direction taken along a line A-A in FIG. 2. As illustrated in FIG. 3, the IGBT 100 includes an n⁻ type drift layer 9 (first semiconductor layer) including a semiconductor substrate. The n⁻ type drift layer 9 is a semiconductor layer containing, for example, arsenic or phosphorus as an n-type impurity, and concentration of the n-type impurity is 1.0×10¹²/cm³ to 1.0×10¹⁵/cm³. In FIG. 3, the semiconductor substrate is in a range from an n⁺ type source layer 6 to a p-type collector layer 12. In FIG. 3, an upper end of the n⁺ type source layer 6 on the paper is referred to as a first main surface of the semiconductor substrate, and a lower end of the p-type collector layer 12 on the paper is referred to as a second main surface of the semiconductor substrate. The first main surface of the semiconductor substrate is a main surface on a front surface side of the IGBT 100, and the second main surface of the semiconductor substrate is a main surface on a back surface side of the IGBT 100.

As illustrated in FIG. 3, an n⁺ type carrier accumulation layer 8 having higher concentration of an n-type impurity than that of the n⁻ type drift layer 9 is provided on the first main surface side of the n⁻ type drift layer 9. The n⁺ type carrier accumulation layer 8 is a semiconductor layer containing, for example, arsenic or phosphorus as the n-type impurity, and concentration of the n-type impurity is 1.0×10¹³/cm³ to 1.0×10¹⁷/cm³. By providing the n⁺ type carrier accumulation layer 8, energization loss when a current flows through the IGBT 100 can be reduced, but the n⁺ type carrier accumulation layer 8 does not have to be provided. The n⁺ type carrier accumulation layer 8 and the n⁻ type drift layer 9 may be collectively referred to as a drift layer.

A p-type base layer 7 (second semiconductor layer) is provided on the first main surface side of the n⁺ type carrier accumulation layer 8. The p-type base layer 7 is a semiconductor layer containing, for example, boron or aluminum as a p-type impurity, and concentration of the p-type impurity is 1.0×10¹²/cm³ to 1.0×10¹⁹/cm³. The p-type base layer 7 is in contact with a trench insulating film 10 (first trench insulating film) of the two-stage trench electrode 30 and a trench insulating film 18 (second trench insulating film) of the one-stage trench electrode 40.

On the first main surface side of the p-type base layer 7, an n⁺ type source layer 6 (third semiconductor layer) is provided in contact with the trench insulating films 10 and 18. The n⁺ type source layer 6 constitutes the first main surface of the semiconductor substrate. The n⁺ type source layer 6 is a semiconductor layer containing, for example, arsenic or phosphorus as the n-type impurity, and concentration of the n-type impurity is 1.0 ×10¹⁷/cm³ to 1.0×10²⁰/cm³.

An n⁺ type buffer layer 11 having higher concentration of the n-type impurity than that of the n⁻ type drift layer 9 is provided on the second main surface side of the n⁻ type drift layer 9. The n⁺ type buffer layer 11 is provided to suppress punch-through of a depletion layer extending from the p-type base layer 7 to the second main surface side when the IGBT 100 is in an off state. The n⁺ type buffer layer 11 may be formed by, for example, injecting phosphorus (P) or protons (H⁺) or may be formed by injecting both phosphorus (P) and protons (H⁺). The concentration of the n-type impurity in the n-type buffer layer 11 is 1.0×10¹²/cm³ to 1.0×10¹⁸/cm³.

A p⁺ type collector layer 12 is provided on the second main surface side of the n-type buffer layer 11. In other words, the p⁺ type collector layer 12 is provided between the n⁻ type drift layer 9 and the second main surface. The p⁺ type collector layer 12 is a semiconductor layer containing, for example, boron or aluminum as the p-type impurity, and concentration of the p-type impurity is 1.0×10¹⁶/cm³ to 1.0×10²⁰/cm³.

The two-stage trench electrode 30 is provided in a trench formed so as to penetrate the p-type base layer 7 from the first main surface of the semiconductor substrate and reach the n⁻ type drift layer 9. In other words, the two-stage trench electrode 30 includes the trench insulating film 10 at a bottom portion and a side wall of the trench, that is, on an inner surface, a lower electrode 19 is provided below the trench surrounded by the trench insulating film 10, and an upper electrode 14 is provided above the lower electrode 19. The lower electrode 19 and the upper electrode 14 are insulated by a partition insulating film 20, and the upper electrode 14 is connected to an emitter potential, and the lower electrode 19 is connected to a gate potential.

In the upper electrode 14, a portion corresponding to the upper side of the lower electrode 19 is a recess, and a side wall of the recess is a pointed portion 15 protruding toward the bottom portion of the trench. The partition insulating film 20 is provided so as to cover an inside of the recess and the pointed portion 15.

The one-stage trench electrode 40 is provided in a trench formed so as to penetrate the p-type base layer 7 from the first main surface of the semiconductor substrate and reach the n⁻ type drift layer 9. In other words, the one-stage trench electrode 40 includes a trench insulating film 18 at the bottom portion and the side wall of the trench, that is, on an inner surface, and includes a trench electrode 17 reaching from the bottom portion of the trench to the first main surface, and a viewing member 16 made of a conductor is embedded in an upper region of the trench insulating film 18 of the side wall.

The trench insulating film 18 of the one-stage trench electrode 40 is in contact with the p-type base layer 7 and the n⁺ type source layer 6. If a gate driving voltage is applied to the trench electrode 17, a channel is formed in the p-type base layer 7 in contact with the trench insulating film 18.

Here, the trench insulating films 10 and 18 and the partition insulating film 20 are made of, for example, a silicon oxide film. The upper electrode 14, the lower electrode 19, the trench electrode 17, and the viewing member 16 are made of any of polysilicon, amorphous silicon, and metal, for example. In addition, the trench refers to an opening provided in the semiconductor substrate, but may also refer to a structure formed in the opening.

Further, as illustrated in FIG. 3, an interlayer insulating film IS is provided on the two-stage trench electrode 30 and the one-stage trench electrode 40, and an emitter electrode 1 (first main electrode) is provided on the first main surface of the semiconductor substrate including the interlayer insulating film IS. A collector electrode 13 (second main electrode) is provided on the second main surface of the semiconductor substrate opposite to the side where the emitter electrode 1 is provided in a thickness direction.

The emitter electrode 1 may be formed with, for example, an aluminum alloy such as an aluminum silicon alloy (Al—Si-based alloy) or may be an electrode including a plurality of layers of metal films in which a plating film is formed on an electrode formed with an aluminum alloy by electroless plating or electrolytic plating.

Similarly to the emitter electrode 1, the collector electrode 13 may be formed with an aluminum alloy or an aluminum alloy, and a plating film. The collector electrode 13 may have a configuration different from that of the emitter electrode 1. The collector electrode 13 is in ohmic contact with the p-type collector layer 12 and is electrically connected to the p-type collector layer 12.

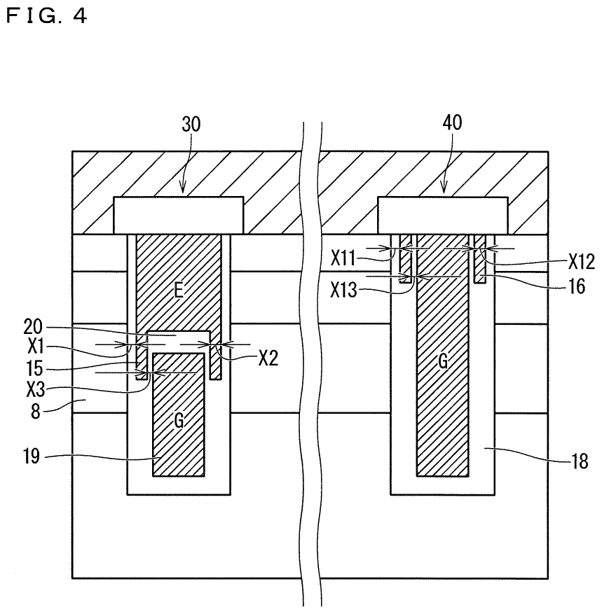

FIG. 4 is a view illustrating a length in a horizontal direction, that is, a thickness of each portion in the two-stage trench electrode 30 and the one-stage trench electrode 40. In FIG. 4, a thickness of the trench insulating film 10 between the trench side wall of the two-stage trench electrode 30 and the pointed portion 15 is set at X1, a thickness of the pointed portion 15 is set at X2, and a thickness of the partition insulating film 20 between the pointed portion 15 and the lower electrode 19 is set at X3. In addition, a thickness of the trench insulating film 18 between the trench side wall of the one-stage trench electrode 40 and the viewing member 16 is set at X11, a thickness of the viewing member 16 is set at X12, and a thickness of the trench insulating film 18 between the viewing member 16 and the trench electrode 17 is set at X13. A relationship among the thicknesses is X1=X11, X2 =X12, and X3=X13.

By managing the thicknesses X1, X2, and X3 of the two-stage trench electrode 30 using the above relationship, the pointed portion 15 having excellent durability can be formed, and reliability of a gate of the IGBT 100 can be improved.

In other words, if the IGBT 100 is turned off, a negative bias is applied between the gate and the emitter. In this case, holes concentrate in the vicinity of the emitter electrode 1. An electric field due to the negative bias and the holes is applied to the emitter electrode 1, and particularly if an interval between the pointed portion 15 formed in the upper electrode 14 and the lower electrode 19, that is, the thickness X3 is narrowed, the electric field concentrates on the pointed portion 15. As described above, the electric field intensity concentrating on the pointed portion 15 depends on the thickness X3 of the partition insulating film 20 between the pointed portion 15 and the lower electrode 19, so that it is possible to improve reliability of the IGBT 100 by managing variation caused by the manufacturing process.

As described in the manufacturing method described later, the thickness X12 of the viewing member 16 embedded in the vicinity of the first main surface in the trench insulating film 18 can be visually recognized from an upper surface of a wafer during the manufacturing process, and thus, the thickness X3 of the partition insulating film 20 between the pointed portion 15 and the lower electrode 19 can be managed from the relationship of X2=X12, and the reliability of the IGBT 100 can be improved.

In the IGBT 100, the upper electrode 14 is connected to the emitter potential and the lower electrode 19 is connected to the gate potential, and thus, a ratio of Cgc/Cge can be increased, and turn-on loss can be reduced.

In addition, if the upper electrode 14 is connected to the emitter potential and the lower electrode 19 is connected to the gate potential, the electric field in the vicinity of the pointed portion 15 of the upper electrode 14 in the vicinity of a mesa portion becomes high at turn-off. However, by managing the thickness X12 of the viewing member 16 embedded in the one-stage trench electrode 40 and the thickness X2 of the partition insulating film 20 between the pointed portion 15 and the lower electrode 19, durability against damage to the pointed portion 15 is improved, and reliability of the IGBT 100 can be improved.

### Manufacturing Method

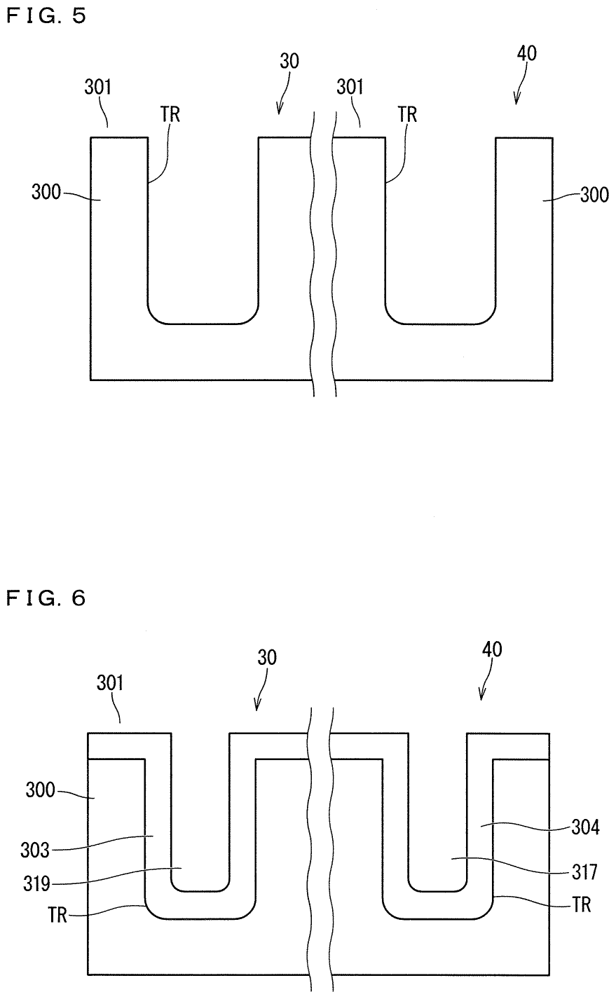

Next, a method of manufacturing the IGBT 100 will be described with reference to FIGS. 5 to 18 sequentially indicating manufacturing processes. Note that only a method of manufacturing the two-stage trench electrode 30 and the one-stage trench electrode 40 will be described below, and a well-known method can be used for a method of manufacturing each portion other than the two-stage trench electrode 30 and the one-stage trench electrode 40, and thus, the description thereof will be omitted.

First, an n-type semiconductor substrate 300 is prepared, and in the process indicated in FIG. 5, in a region of the semiconductor substrate 300 where the two-stage trench electrode 30 and the one-stage trench electrode 40 are to be formed, a trench TR reaching a predetermined depth from a first main surface 301 of the semiconductor substrate 300 and extending in the depth direction on the paper is formed.

Next, in the process indicated in FIG. 6, an insulating film 303 (first insulating film) is formed in a region (first region) where the two-stage trench electrode 30 is to be formed so as to cover an inner surface of the trench TR, and an insulating film 304 (second insulating film) is formed in a region (second region) where the one-stage trench electrode 40 is to be formed.

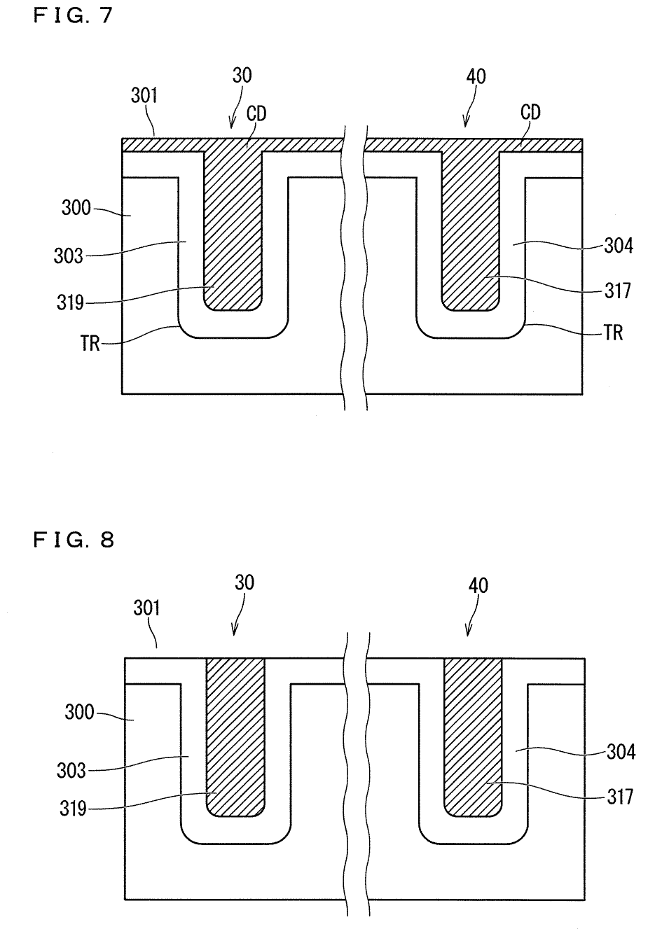

Next, in the process indicated in FIG. 7, a conductor CD is embedded in the trench TR via the insulating films 303 and 304, the lower electrode 319 is formed in a region where the two-stage trench electrode 30 is to be formed, and a trench electrode 317 is formed in a region where the one-stage trench electrode 40 is to be formed. As the conductor CD, for example, polysilicon, amorphous silicon, and a metal can be used.

Next, in the process indicated in FIG. 8, the conductor CD formed above the insulating films 303 and 304 on the first main surface 301 is retracted by, for example, etching to expose the upper surfaces of the insulating films 303 and 304.

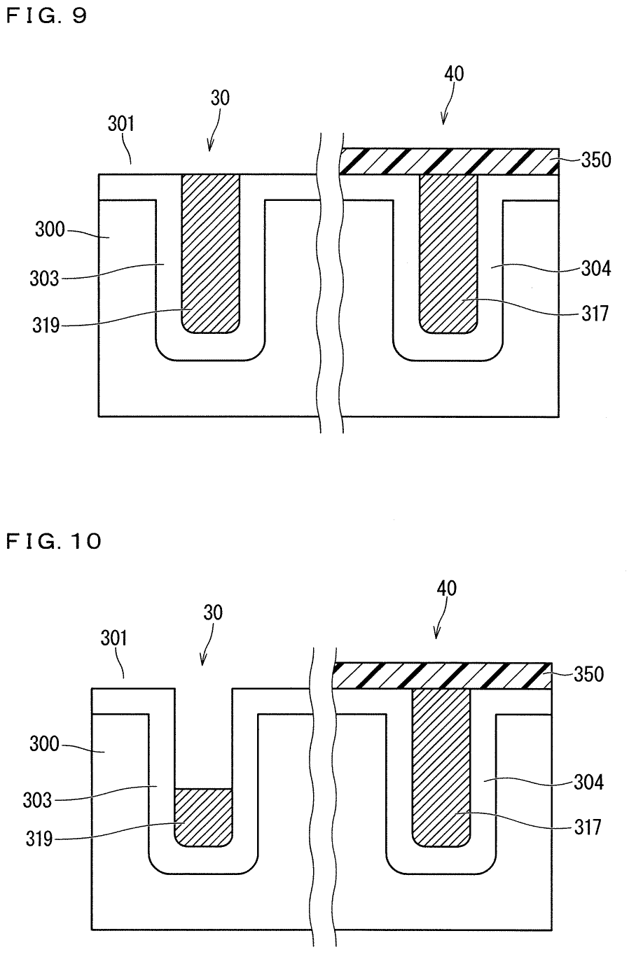

Next, in the process indicated in FIG. 9, a photoresist is applied to the first main surface 301 side, and patterning is performed by photolithography, or the like, to form a resist mask 350.

Next, in the process indicated in FIG. 10, using the resist mask 350 as an etching mask, the lower electrode 319 is retracted into the trench TR, and etching is performed so that the trench electrode 317 remains.

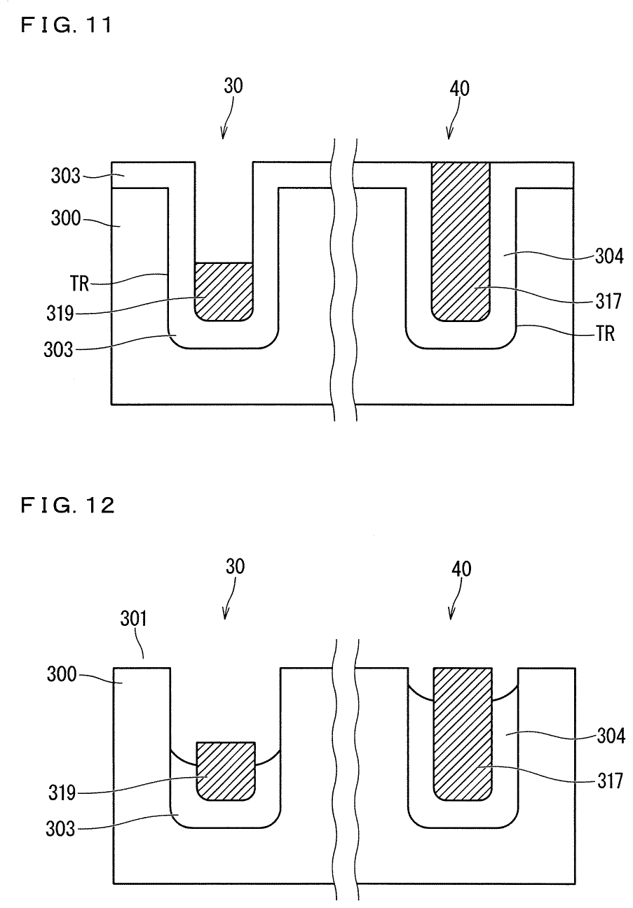

Next, in the process indicated in FIG. 11, the resist mask 350 is removed, and then in the process indicated in FIG. 12, the insulating films 303 and 304 are retracted by etching so that positions of upper ends of the insulating films 303 and 304 are lower than positions of upper ends of the lower electrode 319 and the trench electrode 317.

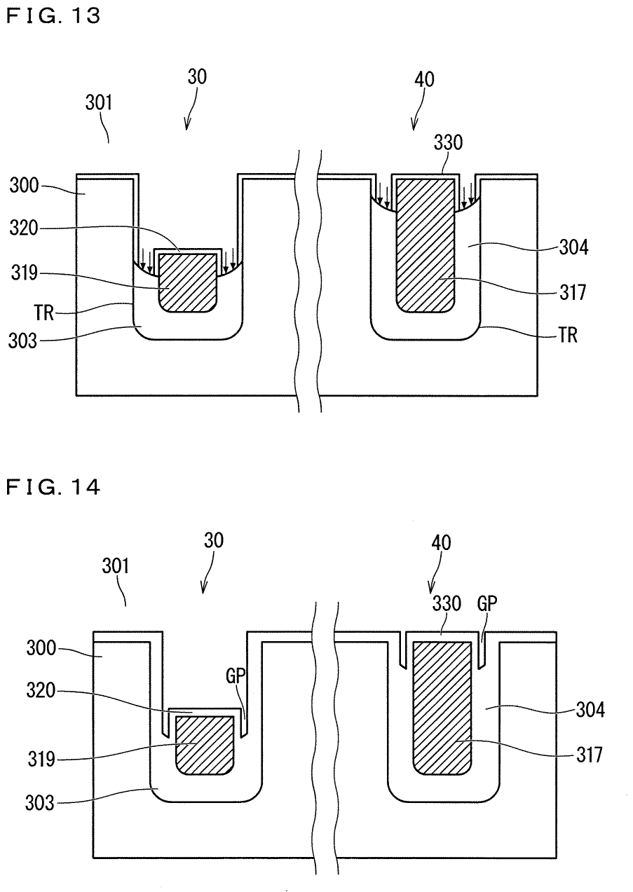

Next, in the process indicated in FIG. 13, an insulating film 320 (third insulating film) is formed on the trench side wall and an upper portion of the lower electrode 319 in a region where the two-stage trench electrode 30 is to be formed, and an insulating film 330 (fourth insulating film) is formed on the trench side wall and an upper portion of the trench electrode 317 in a region where the one-stage trench electrode 40 is to be formed. The insulating films 320 and 330 to be formed have different insulating film formation amounts per unit time on the side wall of the trench, the electrodes, and the retracted insulating films 303 and 304.

In other words, on the retracted insulating films 303 and 304 indicated by arrows in FIG. 13, the insulating films 320 and 330 are hardly formed, and the insulating films 320 and 330 are formed on the trench side wall, the upper end of the lower electrode 319, and the upper end of the trench electrode 317, so that a gap GP for embedding the pointed portion 315 and the viewing member 316 is formed as indicated in FIG. 14.

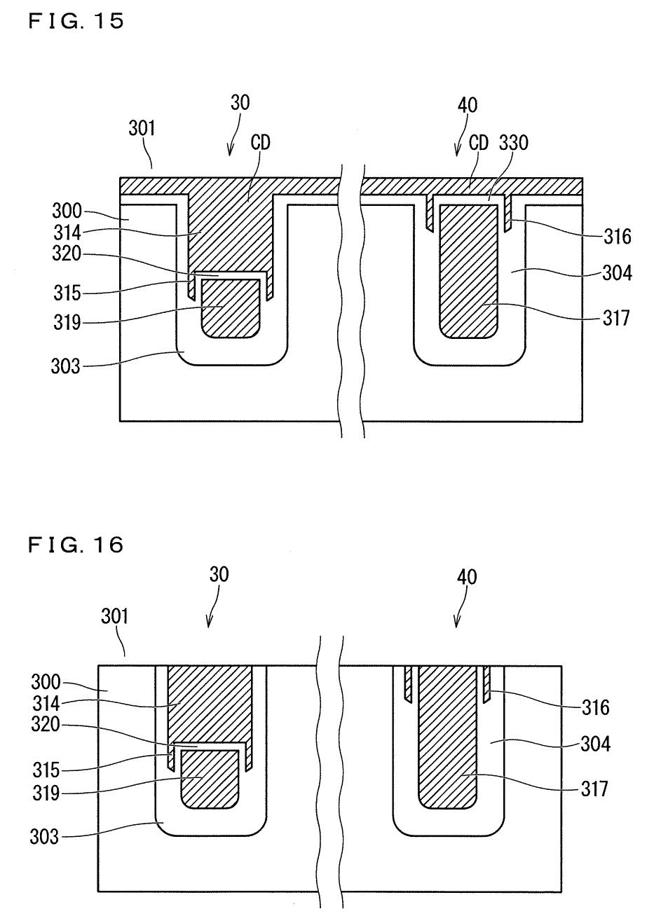

Next, in the process indicated in FIG. 15, the conductor CD is embedded in the trench TR in a state where the insulating films 320 and 330 are formed, the upper electrode 314 including the pointed portion 315 is formed in the region where the two-stage trench electrode 30 is to be formed, and the viewing member 316 is embedded in the region where the one-stage trench electrode 40 is to be formed.

Next, in the process indicated in FIG. 16, the conductor CD formed above the first main surface 301 and the insulating films 320 and 330 are retracted to a height of the first main surface 301.

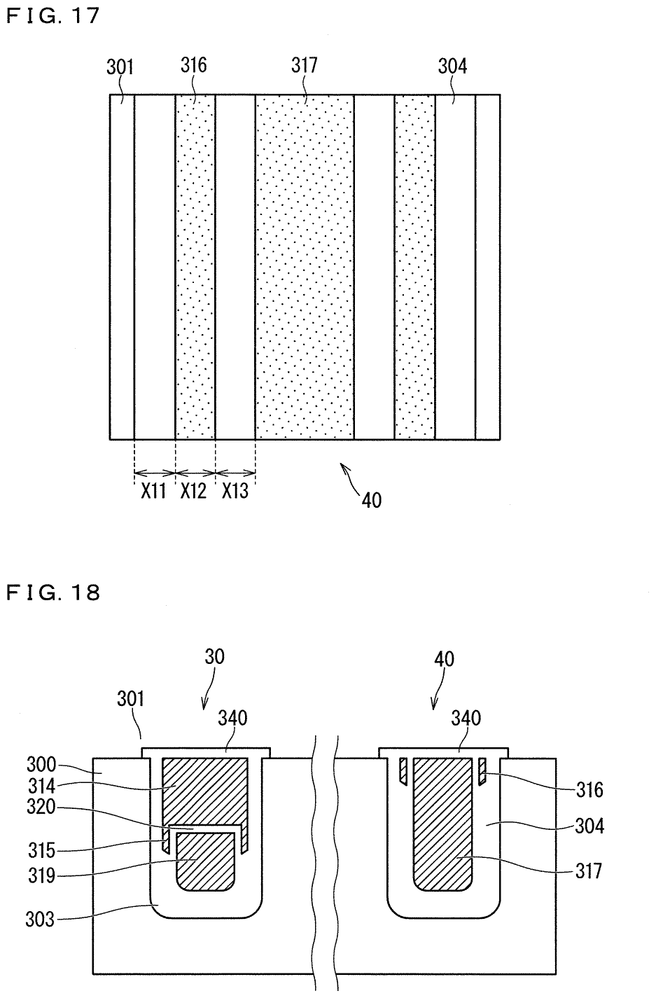

Next, in the process indicated in FIG. 17, the one-stage trench electrode 40 is observed from the first main surface 301 side, a positional relationship among the trench electrode 317, the viewing member 316, and the insulating film 304 is acquired, and a width and a shape of the pointed portion 315 formed under the upper electrode 314 of the two-stage trench electrode 30 are estimated and managed.

In a case where the estimated width and shape of the pointed portion 315 are within a range of design, an insulating film 340 is formed on the two-stage trench electrode 30 and the one-stage trench electrode 40 to form an interlayer insulating film in the process indicated in FIG. 18. The two-stage trench electrode 30 and the one-stage trench electrode 40 can be obtained through the above processes, and the width and the shape of the pointed portion 315 of the two-stage trench electrode 30 can be managed using the viewing member 316 of the one-stage trench electrode 40.

### First Modification

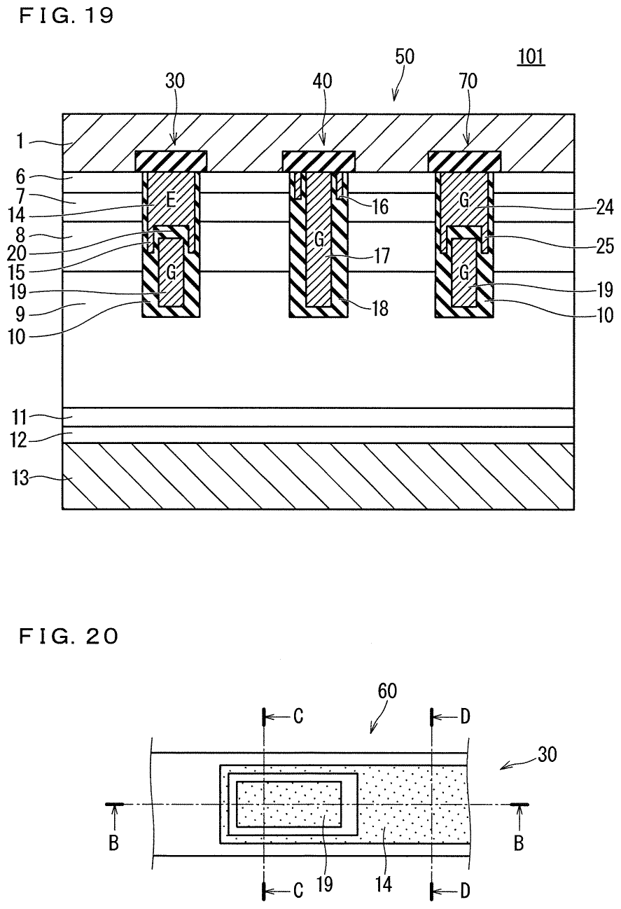

FIG. 19 is a cross-sectional view illustrating a configuration of an IGBT 101 according to a first modification of the first preferred embodiment, and is a view corresponding to a cross-sectional view in an arrow direction taken along the line A-A of the partial region 50 surrounded by the dashed line in the active region AR in FIG. 1.

In the IGBT 100 of the first preferred embodiment illustrated in FIG. 3, the two-stage trench electrode 30 and the one-stage trench electrode 40 are provided in the active region AR, but the IGBT 101 illustrated in FIG. 19 includes the two-stage trench electrode 70 in addition to the two-stage trench electrode 30 and the one-stage trench electrode 40.

A structure of the two-stage trench electrode 70 is basically the same as that of the two-stage trench electrode 30, and the lower electrode 19 is provided below the trench surrounded by the trench insulating film 10, and the upper electrode 24 is provided above the lower electrode 19. The lower electrode 19 and the upper electrode 24 are insulated from each other by the partition insulating film 20, and the two-stage trench electrode 70 is different from the two-stage trench electrode 30 only in that the upper electrode 24 is connected to the gate potential.

In the upper electrode 24, a portion corresponding to the upper side of the lower electrode 19 is a recess, and a side wall of the recess is a pointed portion 25 protruding toward the bottom of the trench. The partition insulating film 20 is provided so as to cover an inside of the recess and the pointed portion 25.

Note that FIG. 19 illustrates an example in which the two-stage trench electrodes 30, the one-stage trench electrodes 40, and the two-stage trench electrodes 70 of the same number are provided, but the number is not limited to the same number, and any one of them can be increased, and any one can be reduced as the total number in the active region AR.

By providing the two-stage trench electrode 70 in which the upper electrode 24 is connected to the gate potential, like the two-stage trench electrode 30, the number of the lower electrodes 19 connected to the emitter potential can be adjusted, and the ratio of Cgc/Cge can be adjusted to a desired value. In other words, Cge decreases as the number of electrodes connected to the emitter potential increases, and thus, Cge can be adjusted by adjusting the number of electrodes connected to the emitter potential, and the ratio of Cgc/Cge can be adjusted.

Here, the two-stage trench electrode 30 and the two-stage trench electrode 70 are used for adjusting the ratio of Cgc/Cge, and thus, they can be referred to as a first adjustment trench electrode and a second adjustment trench electrode, respectively.

### Second Modification

In the IGBT 100 of the first preferred embodiment illustrated in FIG. 3, a potential of the viewing member 16 embedded in the upper region of the trench insulating film 18 of the one-stage trench electrode 40 is not limited, but the viewing member 16 may be connected to either the gate potential or the emitter potential, and may be a floating potential. This is because the viewing member 16 does not function as an electrode and is used only for managing the width and shape of the pointed portion 15 of the two-stage trench electrode 30. By not limiting the potential of the viewing member 16, a degree of freedom in design is increased.

### Second Preferred Embodiment

FIG. 20 is a view illustrating a semiconductor device of a second preferred embodiment, and illustrates a plan view shape of a partial region 60 surrounded by a dashed line in the active region AR of FIG. 1. FIG. 20 is a partial plan view in which an upper structure such as an emitter electrode near the gate wiring 3 is omitted, and is a top view of a wiring lead-out region.

The wiring lead-out region is a region that connects the lower electrode 19 of the two-stage trench electrode 30 to the gate potential, and the lower electrode 19 is exposed at an end portion of the two-stage trench electrode 30.

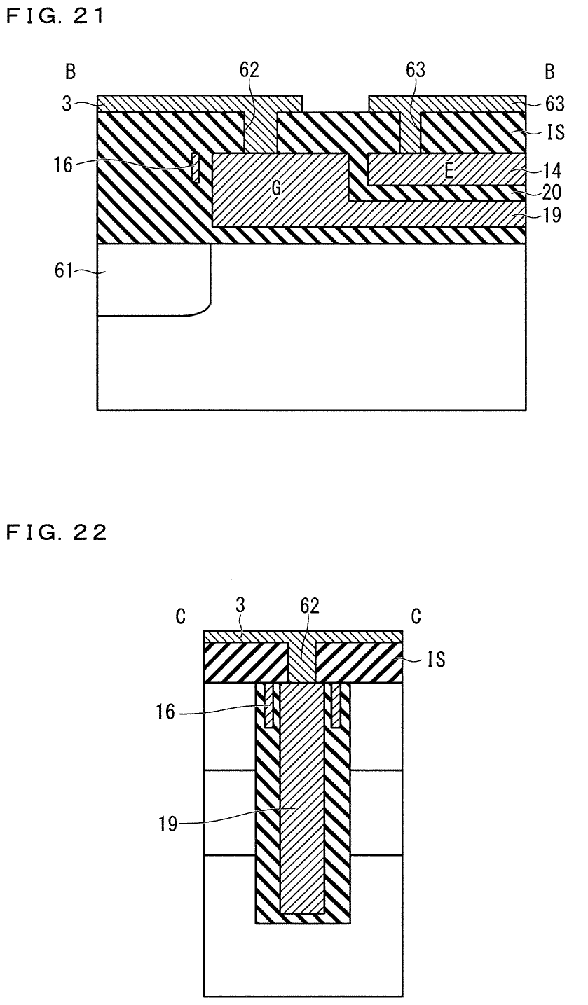

FIG. 21 is a cross-sectional view taken along a line B-B in FIG. 20, FIG. 22 is a cross-sectional view taken along a line C-C in an arrow direction, and FIG. 23 is a cross-sectional view taken along a line D-D in an arrow direction.

As illustrated in FIGS. 21 and 22, the two-stage trench electrode 30 has a structure similar to that of the one-stage trench electrode 40 at the end portion, is provided so as to extend in an upward direction such that the lower electrode 19 is in contact with the interlayer insulating film IS, and is electrically connected to the gate wiring 3 provided on the interlayer insulating film IS via a contact hole 62.

Further, as illustrated in FIG. 23, the two-stage trench electrode 30 has a structure of the two-stage trench electrode 30 in a portion other than the end portion, and the upper electrode 14 is in contact with the interlayer insulating film IS and is electrically connected to an emitter wiring 64 provided on the interlayer insulating film IS via a contact hole 63.

As illustrated in FIG. 21, a p-type termination well region 61 is provided on the termination region 5 side that is outside the end portion of the two-stage trench electrode 30.

As described above, in the wiring lead-out region, the end portion of the two-stage trench electrode 30 has the same structure as that of the one-stage trench electrode 40, and thus, the width and the shape of the pointed portion 15 of the two-stage trench electrode 30 can be managed using the viewing member 16 of the one-stage trench electrode 40 as illustrated in FIG. 22.

### Third Preferred Embodiment

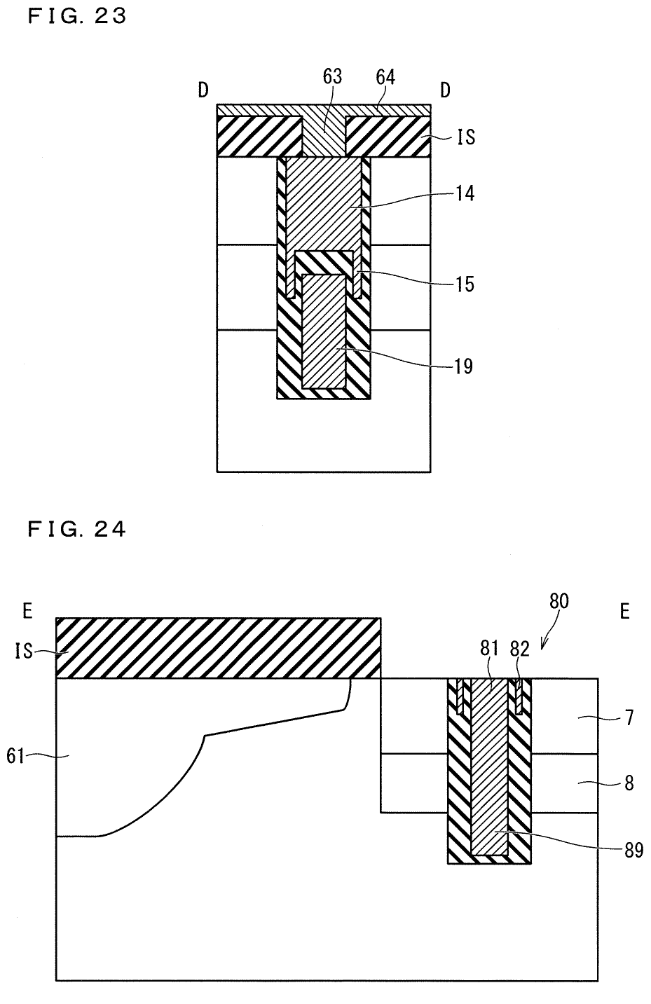

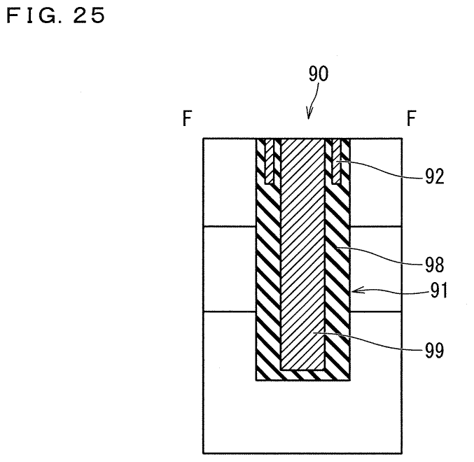

FIG. 24 is a view for explaining a semiconductor device of a third preferred embodiment, and is a cross-sectional view in an arrow direction taken along a line E-E of a partial region 80 surrounded by a dashed line in the active region AR in FIG. 1. The partial region 80 is the termination region 5 outside the active region AR, and a one-stage trench electrode 81 formed in the termination region has the same structure as that of the one-stage trench electrode 40, includes a trench insulating film 88 at a bottom portion and a side wall of the trench, that is, an inner surface, includes a trench electrode 89 reaching the first main surface from the bottom portion of the trench, and a viewing member 82 made of a conductor is embedded in an upper region of the trench insulating film 88 of the side wall. Thus, the width and shape of the pointed portion 15 of the two-stage trench electrode 30 can be managed using the viewing member 82.

Note that a p-type termination well region 61 is provided outside the one-stage trench electrode 81, and an interlayer insulating film IS is provided on the p-type termination well region 61. In addition, although nothing is illustrated in the structure on the region where the one-stage trench electrode 81 is provided, an emitter electrode may be provided here, or an interlayer insulating film may be provided here. The width and the shape of the pointed portion 15 of the two-stage trench electrode 30 are managed using the viewing member 82, and thus, any potential may be applied to the one-stage trench electrode 81, and the one-stage trench electrode may have a floating potential.

### Fourth Preferred Embodiment

FIG. 25 is a view for explaining a semiconductor device according to a fourth preferred embodiment, and is a cross-sectional view taken along a line F-F of a partial region 90 surrounded by a dashed line in a region where the dicing line 4 is formed in FIG. 1. As illustrated in FIG. 25, a one-stage trench electrode 91 is formed in the partial region 90. The one-stage trench electrode 91 has a structure similar to that of the one-stage trench electrode 40, includes a trench insulating film 98 at a bottom portion and a side wall of the trench, that is, on an inner surface, and includes a trench electrode 99 reaching from the bottom portion of the trench to the first main surface, and a viewing member 92 including a conductor is embedded in an upper region of the trench insulating film 98 of the side wall. Thus, a width and a shape of the pointed portion 15 of the two-stage trench electrode 30 can be managed using the viewing member 92.

### Fifth Preferred Embodiment

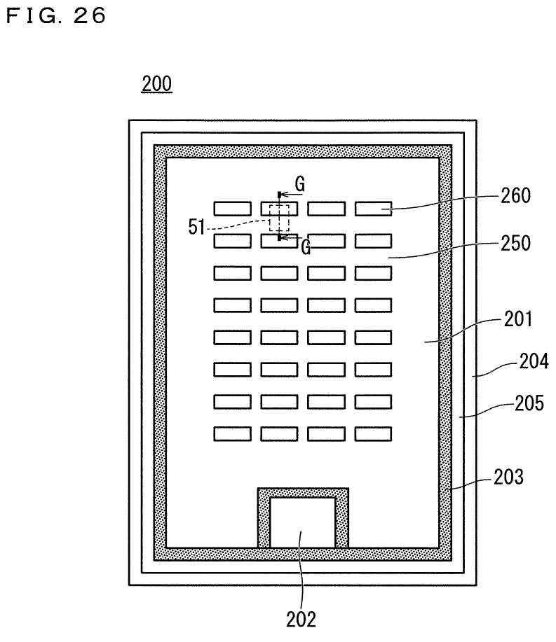

FIG. 26 is a plan view schematically illustrating an entire upper surface configuration of a reverse conducting IGBT (RC-IGBT) 200 according to the second preferred embodiment of the present disclosure. The RC-IGBT 200 includes an IGBT region 250 and a diode region 260 in one semiconductor substrate.

A plurality of diode regions 260 is arranged side by side in a longitudinal direction and a lateral direction in the RC-IGBT 200, and the diode regions 260 are surrounded by the IGBT region 250. In other words, the plurality of diode regions 260 is provided in an island shape in the IGBT region 250. Note that the number of diode regions 260 is not limited to the number illustrated in FIG. 26.

In the RC-IGBT 200, similarly to the IGBT 100 illustrated in FIG. 1, the outer side of the active region AR is a termination region 205. In the active region AR, a plurality of trench electrodes (not illustrated) is provided in parallel at intervals. The plurality of trench electrodes is connected to a gate wiring 203 provided in the active region AR, and the gate wiring 203 is connected to a gate pad 202. A dicing line 204 is provided outside the termination region 205. Note that shapes and arrangement of the gate wiring 203 and the gate pad 202 are not limited to those in FIG. 26.

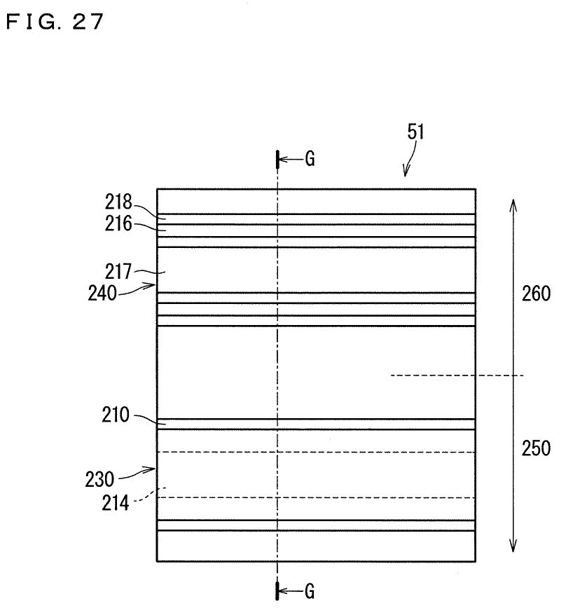

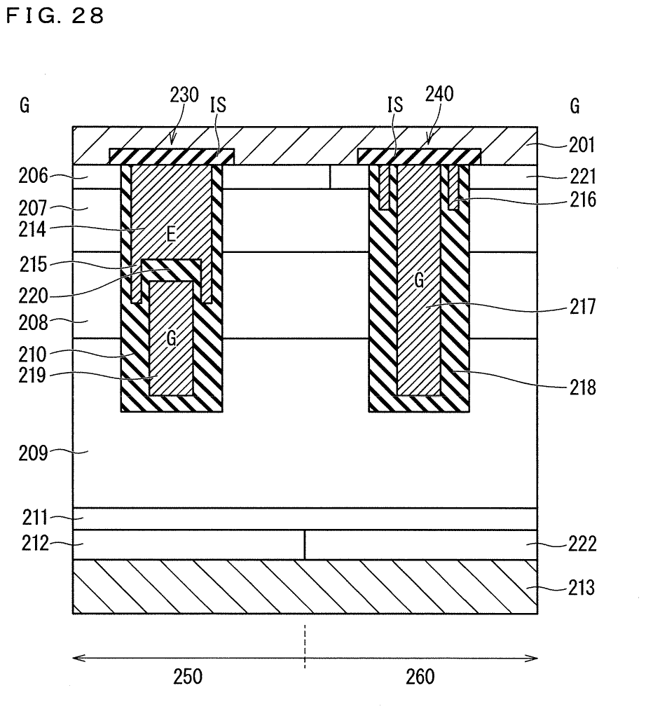

A plan view shape of a partial region 51 surrounded by a dashed line in the active region AR of FIG. 26 is illustrated in FIG. 27. FIG. 27 is a partial plan view in which an upper structure such as an emitter electrode in the active region AR is omitted.

As illustrated in FIG. 27, in the active region AR, a stripe-shaped two-stage trench electrode 230 and a stripe-shaped one-stage trench electrode 240 are provided in parallel. The two-stage trench electrode 230 and the one-stage trench electrode 240 are provided so as to extend in parallel to an arrangement direction of the plurality of diode regions 260 in the horizontal direction on the paper. Note that the extending direction of the two-stage trench electrode 230 and the one-stage trench electrode 240 is not limited thereto, and a vertical direction on the paper may be the extending direction.

FIG. 28 is a cross-sectional view taken along a line G-G in FIG. 27 in an arrow direction. As illustrated in FIG. 28, the IGBT region 250 of the RC-IGBT 200 includes an n⁻ type drift layer 209 (first semiconductor layer) including a semiconductor substrate. The n⁻ type drift layer 209 is the same as the n⁻ type drift layer 9 of the IGBT 100.

In FIG. 28, the semiconductor substrate is in a range from the n⁺ type source layer 206 to the p-type collector layer 212. In FIG. 28, the upper end of the n⁺ type source layer 206 on the paper is referred to as a first main surface of the semiconductor substrate, and the lower end of the p-type collector layer 212 on the paper is referred to as a second main surface of the semiconductor substrate.

As illustrated in FIG. 28, an n⁺ type carrier accumulation layer 208 having higher n-type impurity concentration than that of the n⁻ type drift layer 209 is provided on the first main surface side of the n⁻ type drift layer 209. The n⁺ type carrier accumulation layer 208 is the same as the n⁺ type carrier accumulation layer 208 of the IGBT 100.

A p-type base layer 207 (second semiconductor layer) is provided on the first main surface side of the n⁺ type carrier accumulation layer 208. The p-type base layer 207 is the same as the p-type base layer 207 of the IGBT 100.

The p-type base layer 207 is in contact with a trench insulating film 210 (first trench insulating film) of the two-stage trench electrode 230 and the trench insulating film 218 (second trench insulating film) of the one-stage trench electrode 240.

On the first main surface side of the p-type base layer 207, an n⁺ type source layer 206 (third semiconductor layer) is provided in contact with the trench insulating film 210. The n⁺ type source layer 206 is the same as the n⁺ type source layer 6 of the IGBT 100.

An n⁺ type buffer layer 211 (fourth semiconductor layer) having higher concentration of n-type impurity than that of the n⁻ type drift layer 209 is provided on the second main surface side of the n-type drift layer 209. The n⁺ type buffer layer 211 is the same as the n⁺ type buffer layer 11 of the IGBT 100.

A p⁺ type collector layer 212 is provided on the second main surface side of the n-type buffer layer 211. The p⁺ type collector layer 212 is the same as the p⁺ type collector layer 12 of the IGBT 100.

In the diode region 260 of the RC-IGBT 200 illustrated in FIG. 28, the same components as those of the IGBT region 250 are denoted by the same reference numerals, and redundant description is omitted.

As illustrated in FIG. 28, in the diode region 260, a p-type anode layer 221 (fifth semiconductor layer) is provided instead of the n⁺ type source layer 206, and an n⁺ type cathode layer 222 (sixth semiconductor layer) is provided instead of the p⁺ type collector layer 212.

The p-type anode layer 221 is a semiconductor layer containing, for example, boron or aluminum as a p-type impurity, and concentration of the p-type impurity is 1.0×10¹²/cm³ to 1.0×10¹⁹/cm³. The n⁺ type cathode layer 222 is a semiconductor layer containing, for example, arsenic or phosphorus as an n-type impurity, and concentration of the n-type impurity is 1.0×10¹⁶/cm³ to 1.0×10²¹/cm³.

The two-stage trench electrode 230 is provided in a trench formed so as to penetrate the p-type base layer 207 from the first main surface of the semiconductor substrate and reach the n⁻ type drift layer 209. In other words, the two-stage trench electrode 230 includes the trench insulating film 210 at a bottom portion and a side wall of the trench, that is, on an inner surface, a lower electrode 219 is provided below the trench surrounded by the trench insulating film 210, and an upper electrode 214 is provided above the lower electrode 219. The lower electrode 219 and the upper electrode 214 are insulated by a partition insulating film 220, and the upper electrode 214 is connected to an emitter potential and the lower electrode 219 is connected to a gate potential.

In the upper electrode 214, a portion corresponding to the upper side of the lower electrode 219 is a recess, and a side wall of the recess is a pointed portion 215 protruding toward the bottom portion of the trench. The partition insulating film 220 is provided so as to cover an inside of the recess and the pointed portion 15.

The one-stage trench electrode 240 is provided in a trench formed so as to penetrate the p-type base layer 207 from the first main surface of the semiconductor substrate and reach the n⁻ type drift layer 209. In other words, the one-stage trench electrode 240 includes the trench insulating film 218 at the bottom portion and the side wall of the trench, that is, on the inner surface, and includes the trench electrode 217 reaching from the bottom portion of the trench to the first main surface, and the viewing member 216 including a conductor is embedded in an upper region of the trench insulating film 218 of the side wall.

The two-stage trench electrode 230 and the one-stage trench electrode 240 are the same as the two-stage trench electrode 30 and the one-stage trench electrode 40 of the IGBT 100, respectively.

As illustrated in FIG. 28, the interlayer insulating film IS is provided on the two-stage trench electrode 230 and the one-stage trench electrode 240, and an emitter electrode 201 (first main electrode) is provided on the first main surface of the semiconductor substrate including the interlayer insulating film IS. A collector electrode 213 (second main electrode) also functioning as a cathode electrode is provided on the second main surface of the semiconductor substrate opposite to the side where the emitter electrode 201 is provided in a thickness direction.

The viewing member 216 of the one-stage trench electrode 240 and the pointed portion 215 of the two-stage trench electrode 230 are formed with the same member, and thus, formation conditions are the same, and by managing a width and a shape of the pointed portion 215 of the two-stage trench electrode 230 using the viewing member 216, durability against damage to the pointed portion 215 can be improved, and reliability of the RC-IGBT 200 can be improved.

Note that in the present disclosure, the embodiments can be freely combined, and the embodiments can be appropriately modified or omitted within a range of the disclosure.

The present disclosure described above will be collectively described as appendixes.

### (Appendix 1)

A semiconductor device comprising:

a semiconductor substrate that includes at least:

a first semiconductor layer of a first conductivity type;

a second semiconductor layer of a second conductivity type on the first semiconductor layer; and

a third semiconductor layer of the first conductivity type provided in an upper layer portion of the second semiconductor layer;

a first trench electrode and a second trench electrode provided inside a trench that penetrates the third semiconductor layer and the second semiconductor layer of the semiconductor substrate in a thickness direction and reaches an inside of the first semiconductor layer;

an interlayer insulating film covering the first and second trench electrodes;

a first main electrode in contact with the third semiconductor layer; and

a second main electrode provided on a side opposite to the first main electrode in the thickness direction of the semiconductor substrate, wherein

the first trench electrode has a two-stage structure including:

a lower electrode provided on a lower side that is the second main electrode side;

an upper electrode provided on an upper side that is the first main electrode side;

a first trench insulating film covering an inner surface of the trench; and

a partition insulating film provided between the lower electrode and the upper electrode,

in the upper electrode, a portion corresponding to an upper side of the lower electrode is a recess, and a side wall of the recess is a pointed portion protruding toward a bottom portion of the trench,

the partition insulating film is provided to cover an inside of the recess and the pointed portion,

the second trench electrode includes:

a second trench insulating film covering an inner surface of the trench;

a trench electrode with which the trench covered with the second trench insulating film is filled; and

a viewing member embedded in an upper region of the second trench insulating film,

the upper electrode is connected to a potential of the first main electrode, and

the lower electrode and the trench electrode are connected to a gate potential.

### (Appendix 2)

A semiconductor device comprising:

a semiconductor substrate including:

a first region that includes at least:

a first semiconductor layer of a first conductivity type;

a second semiconductor layer of a second conductivity type on the first semiconductor layer;

a third semiconductor layer of the first conductivity type provided in an upper layer portion of the second semiconductor layer; and

a fourth semiconductor layer of the second conductivity type provided in the first semiconductor layer opposite to the third semiconductor layer in a thickness direction;

a second region that includes at least:

the first semiconductor layer;

the second semiconductor layer;

a fifth semiconductor layer of the first conductivity type provided in an upper layer portion of the third semiconductor layer; and

a sixth semiconductor layer of the second conductivity type provided in the first semiconductor layer opposite to the fifth semiconductor layer in the thickness direction;

a first trench electrode provided inside a first trench that penetrates the third semiconductor layer and the second semiconductor layer in the first region in the thickness direction and reaches an inside of the first semiconductor layer;

a second trench electrode provided inside a second trench that penetrates the fifth semiconductor layer and the second semiconductor layer in the second region in the thickness direction and reaches the inside of the first semiconductor layer;

an interlayer insulating film covering the first and second trench electrodes;

a first main electrode in contact with the third semiconductor layer and the fifth semiconductor layer; and

a second main electrode provided on a side opposite to the first main electrode in the thickness direction of the semiconductor substrate, wherein

the first trench electrode has a two-stage structure including:

a lower electrode provided on a lower side that is the second main electrode side;

an upper electrode provided on an upper side that is the first main electrode side;

a first trench insulating film covering an inner surface of the first trench; and

a partition insulating film provided between the lower electrode and the upper electrode,

in the upper electrode, a portion corresponding to an upper side of the lower electrode is a recess, and a side wall of the recess is a pointed portion protruding toward a bottom of the trench,

the partition insulating film is provided to cover an inside of the recess and the pointed portion,

the second trench electrode includes:

a second trench insulating film covering an inner surface of the second trench;

a trench electrode with which the trench covered with the second trench insulating film is filled; and

a viewing member embedded in an upper region of the second trench insulating film,

the upper electrode is connected to a potential of the first main electrode, and

the lower electrode and the trench electrode are connected to a gate potential.

### (Appendix 3)

The semiconductor device according to Appendix 1 or 2, wherein

in a case where a thickness of the first trench insulating film between a side wall of the trench of the first trench electrode and the pointed portion is set at X1,

a thickness of the pointed portion is set at X2,

a thickness of the partition insulating film between the pointed portion and the lower electrode is set at X3,

a thickness of the second trench insulating film between the side wall of the trench of the second trench electrode and the viewing member is set at X11,

a thickness of the viewing member is set at X12, and

a thickness of the second trench insulating film between the viewing member and the trench electrode is set at X13,

a relationship of X1=X11, X2=X12, and X3=X13 is satisfied.

### (Appendix 4)

The semiconductor device according to Appendix 3, wherein

the first trench electrode includes:

a first adjustment trench electrode in which the upper electrode is connected to a potential of the first main electrode, and the lower electrode is connected to the gate potential; and

a second adjustment trench electrode in which the upper electrode and the lower electrode are connected to the gate potential.

### (Appendix 5)

The semiconductor device according to Appendix 3, wherein the viewing member is connected to any one of a potential of the first main electrode, the gate potential, and a floating potential.

### (Appendix 6)

The semiconductor device according to Appendix 4 or 5, wherein

the first and second trench electrodes are arranged at intervals from each other so that a longitudinal direction of each of the first and second trench electrodes is parallel in an active region through which a main current flows,

the first trench electrode has the same structural portion as a structural portion of the second trench electrode at an end portion in the longitudinal direction, and

the lower electrode is connected to the trench electrode of the structural portion and is electrically connected to a gate wiring provided along an outer periphery of the active region via the trench electrode.

### (Appendix 7)

The semiconductor device according to Appendix 4 or 5, wherein

the first and second trench electrodes are arranged at intervals from each other so that a longitudinal direction of each of the first and second trench electrodes is parallel in an active region through which a main current flows, and

the second trench electrode is also arranged in a termination region outside the active region.

### (Appendix 8)

The semiconductor device according to Appendix 4 or 5, wherein

the first and second trench electrodes are arranged at intervals from each other so that a longitudinal direction of each of the first and second trench electrodes is parallel in an active region through which a main current flows, and

the second trench electrode is also arranged on a dicing line on an outermost side of the active region.

### (Appendix 9)

The semiconductor device according to any one of Appendixes 1 to 8, wherein the viewing member and the upper electrode are made of the same conductor.

### (Appendix 10)

A method of manufacturing a semiconductor device, comprising steps of:
(a) forming first and second trenches reaching a predetermined depth from a main surface of a semiconductor substrate;
(b) forming a first insulating film on an inner surface of the first trench and forming a second insulating film on an inner surface of the second trench;
(c) embedding a conductor through the first and second insulating films, forming a lower electrode in the first trench, and forming a trench electrode in the first trench;
(d) removing the conductor above the first and second insulating films on the main surface;
(e) selectively forming a resist mask so as to cover the second trench;
(f) performing etching using the resist mask as an etching mask so that the lower electrode is retracted into the first trench and the trench electrode remains;
(g) removing the first and second insulating films by performing etching so that upper ends of the first and second insulating films are lower than upper ends of the lower electrode and the trench electrode after removing the resist mask;
(h) forming a third insulating film on a side wall of the first trench and an upper portion of the lower electrode and forming a fourth insulating film on a side wall of the second trench and an upper portion of the trench electrode;
(i) embedding the conductor in the first and second trenches in a state where the third and fourth insulating films are formed, forming an upper electrode including a pointed portion in the first trench, and embedding a viewing member in the second trench;
(j) removing the conductor and the third and fourth insulating films on the main surface;
(k) observing the trench electrode from a side of the main surface, acquiring a positional relationship among the trench electrode, the viewing member, and the second insulating film, and estimating and managing a width and a shape of the pointed portion of the first trench; and
(l) forming an interlayer insulating film above the first and second trenches in a case where the estimated width and shape of the pointed portion are within a range of design.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate that includes at least:
a first semiconductor layer of a first conductivity type;
a second semiconductor layer of a second conductivity type on the first semiconductor layer; and
a third semiconductor layer of the first conductivity type provided in an upper layer portion of the second semiconductor layer;
a first trench electrode and a second trench electrode provided inside a trench that penetrates the third semiconductor layer and the second semiconductor layer of the semiconductor substrate in a thickness direction and reaches an inside of the first semiconductor layer;
an interlayer insulating film covering the first and the second trench electrodes;
a first main electrode in contact with the third semiconductor layer; and
a second main electrode provided on a side opposite to the first main electrode in the thickness direction of the semiconductor substrate, wherein
the first trench electrode has a two-stage structure including:
a lower electrode provided on a lower side that is the second main electrode side;
an upper electrode provided on an upper side that is the first main electrode side;
a first trench insulating film covering an inner surface of the trench; and
a partition insulating film provided between the lower electrode and the upper electrode,
in the upper electrode, a portion corresponding to an upper side of the lower electrode is a recess, and a side wall of the recess is a pointed portion protruding toward a bottom portion of the trench,
the partition insulating film is provided to cover an inside of the recess and the pointed portion,
the second trench electrode includes:
a second trench insulating film covering an inner surface of the trench;
a trench electrode with which the trench covered with the second trench insulating film is filled; and
a viewing member embedded in an upper region of the second trench insulating film,
the upper electrode is connected to a potential of the first main electrode, and
the lower electrode and the trench electrode are connected to a gate potential.

2. The semiconductor device according to claim 1, wherein
in a case where a thickness of the first trench insulating film between a side wall of the trench of the first trench electrode and the pointed portion is set at X1,
a thickness of the pointed portion is set at X2,
a thickness of the partition insulating film between the pointed portion and the lower electrode is set at X3,
a thickness of the second trench insulating film between the side wall of the trench of the second trench electrode and the viewing member is set at X11,
a thickness of the viewing member is set at X12, and
a thickness of the second trench insulating film between the viewing member and the trench electrode is set at X13,
a relationship of X1=X11, X2=X12, and X3=X13 is satisfied.

3. The semiconductor device according to claim 2, wherein
the first trench electrode includes:
a first adjustment trench electrode in which the upper electrode is connected to a potential of the first main electrode, and the lower electrode is connected to the gate potential; and
a second adjustment trench electrode in which the upper electrode and the lower electrode are connected to the gate potential.

4. The semiconductor device according to claim 2, wherein the viewing member is connected to any one of a potential of the first main electrode, the gate potential, and a floating potential.

5. The semiconductor device according to claim 3, wherein
the first and second trench electrodes are arranged at intervals from each other so that a longitudinal direction of each of the first and second trench electrodes is parallel in an active region through which a main current flows,
the first trench electrode has the same structural portion as a structural portion of the second trench electrode at an end portion in the longitudinal direction, and
the lower electrode is connected to the trench electrode of the structural portion and is electrically connected to a gate wiring provided along an outer periphery of the active region via the trench electrode.

6. The semiconductor device according to claim 3, wherein
the first and second trench electrodes are arranged at intervals from each other so that a longitudinal direction of each of the first and second trench electrodes is parallel in an active region through which a main current flows, and
the second trench electrode is also arranged in a termination region outside the active region.

7. The semiconductor device according to claim 3, wherein
the first and second trench electrodes are arranged at intervals from each other so that a longitudinal direction of each of the first and second trench electrodes is parallel in an active region through which a main current flows, and
the second trench electrode is also arranged on a dicing line on an outermost side of the active region.

8. The semiconductor device according to claim 4, wherein
the first and second trench electrodes are arranged at intervals from each other so that a longitudinal direction of each of the first and second trench electrodes is parallel in an active region through which a main current flows,
the first trench electrode has the same structural portion as a structural portion of the second trench electrode at an end portion in the longitudinal direction, and
the lower electrode is connected to the trench electrode of the structural portion and is electrically connected to a gate wiring provided along an outer periphery of the active region via the trench electrode.

9. The semiconductor device according to claim 4, wherein
the first and second trench electrodes are arranged at intervals from each other so that a longitudinal direction of each of the first and second trench electrodes is parallel in an active region through which a main current flows, and
the second trench electrode is also arranged in a termination region outside the active region.

10. The semiconductor device according to claim 4, wherein
the first and second trench electrodes are arranged at intervals from each other so that a longitudinal direction of each of the first and second trench electrodes is parallel in an active region through which a main current flows, and
the second trench electrode is also arranged on a dicing line on an outermost side of the active region.

11. The semiconductor device according to claim 1, wherein the viewing member and the upper electrode are made of the same conductor.

12. A semiconductor device comprising:
a semiconductor substrate including:
a first region that includes at least:
a first semiconductor layer of a first conductivity type;
a second semiconductor layer of a second conductivity type on the first semiconductor layer;
a third semiconductor layer of the first conductivity type provided in an upper layer portion of the second semiconductor layer; and
a fourth semiconductor layer of the second conductivity type provided in the first semiconductor layer opposite to the third semiconductor layer in a thickness direction; and
a second region that includes at least:
the first semiconductor layer;
the second semiconductor layer;
a fifth semiconductor layer of the first conductivity type provided in an upper layer portion of the third semiconductor layer; and
a sixth semiconductor layer of the second conductivity type provided in the first semiconductor layer opposite to the fifth semiconductor layer in the thickness direction;
a first trench electrode provided inside a first trench that penetrates the third semiconductor layer and the second semiconductor layer in the first region in the thickness direction and reaches an inside of the first semiconductor layer;
a second trench electrode provided inside a second trench that penetrates the fifth semiconductor layer and the second semiconductor layer in the second region in the thickness direction and reaches the inside of the first semiconductor layer;
an interlayer insulating film covering the first and second trench electrodes;
a first main electrode in contact with the third semiconductor layer and the fifth semiconductor layer; and
a second main electrode provided on a side opposite to the first main electrode in the thickness direction of the semiconductor substrate,
the first trench electrode has a two-stage structure including:
a lower electrode provided on a lower side that is the second main electrode side;
an upper electrode provided on an upper side that is the first main electrode side;
a first trench insulating film covering an inner surface of the first trench; and
a partition insulating film provided between the lower electrode and the upper electrode,
in the upper electrode, a portion corresponding to an upper side of the lower electrode is a recess, and a side wall of the recess is a pointed portion protruding toward a bottom portion of the trench,
the partition insulating film is provided to cover an inside of the recess and the pointed portion,
the second trench electrode includes:
a second trench insulating film covering an inner surface of the second trench;
a trench electrode with which the trench covered with the second trench insulating film is filled; and
a viewing member embedded in an upper region of the second trench insulating film,
the upper electrode is connected to a potential of the first main electrode, and
the lower electrode and the trench electrode are connected to a gate potential.

13. The semiconductor device according to claim 12, wherein
in a case where a thickness of the first trench insulating film between a side wall of the trench of the first trench electrode and the pointed portion is set at X1,
a thickness of the pointed portion is set at X2,
a thickness of the partition insulating film between the pointed portion and the lower electrode is set at X3,
a thickness of the second trench insulating film between the side wall of the trench of the second trench electrode and the viewing member is set at X11,
a thickness of the viewing member is set at X12, and
a thickness of the second trench insulating film between the viewing member and the trench electrode is set at X13,
a relationship of X1=X11, X2=X12, and X3=X13 is satisfied.

14. The semiconductor device according to claim 13, wherein
the first trench electrode includes:
a first adjustment trench electrode in which the upper electrode is connected to a potential of the first main electrode, and the lower electrode is connected to the gate potential; and
a second adjustment trench electrode in which the upper electrode and the lower electrode are connected to the gate potential.

15. The semiconductor device according to claim 13, wherein the viewing member is connected to any one of a potential of the first main electrode, the gate potential, and a floating potential.

16. The semiconductor device according to claim 14, wherein
the first and second trench electrodes are arranged at intervals from each other so that a longitudinal direction of each of the first and second trench electrodes is parallel in an active region through which a main current flows,
the first trench electrode has the same structural portion as a structural portion of the second trench electrode at an end portion in the longitudinal direction, and
the lower electrode is connected to the trench electrode of the structural portion and is electrically connected to a gate wiring provided along an outer periphery of the active region via the trench electrode.

17. The semiconductor device according to claim 14, wherein
the first and second trench electrodes are arranged at intervals from each other so that a longitudinal direction of each of the first and second trench electrodes is parallel in an active region through which a main current flows, and
the second trench electrode is also arranged in a termination region outside the active region.

18. The semiconductor device according to claim 14, wherein
the first and second trench electrodes are arranged at intervals from each other so that a longitudinal direction of each of the first and second trench electrodes is parallel in an active region through which a main current flows, and
the second trench electrode is also arranged on a dicing line on an outermost side of the active region.

19. The semiconductor device according to claim 15, wherein
the first and second trench electrodes are arranged at intervals from each other so that a longitudinal direction of each of the first and second trench electrodes is parallel in an active region through which a main current flows,
the first trench electrode has the same structural portion as a structural portion of the second trench electrode at an end portion in the longitudinal direction, and
the lower electrode is connected to the trench electrode of the structural portion and is electrically connected to a gate wiring provided along an outer periphery of the active region via the trench electrode.

20. The semiconductor device according to claim 15, wherein
the first and second trench electrodes are arranged at intervals from each other so that a longitudinal direction of each of the first and second trench electrodes is parallel in an active region through which a main current flows, and
the second trench electrode is also arranged in a termination region outside the active region.

21. The semiconductor device according to claim 15, wherein
the first and second trench electrodes are arranged at intervals from each other so that a longitudinal direction of each of the first and second trench electrodes is parallel in an active region through which a main current flows, and
the second trench electrode is also arranged on a dicing line on an outermost side of the active region.

22. A method of manufacturing a semiconductor device, comprising steps of:
(a) forming first and second trenches reaching a predetermined depth from a main surface of a semiconductor substrate;
(b) forming a first insulating film on an inner surface of the first trench and forming a second insulating film on an inner surface of the second trench;
(c) embedding a conductor through the first and second insulating films, forming a lower electrode in the first trench, and forming a trench electrode in the first trench;
(d) removing the conductor above the first and second insulating films on the main surface;
(e) selectively forming a resist mask so as to cover the second trench;
(f) performing etching using the resist mask as an etching mask so that the lower electrode is retracted into the first trench and the trench electrode remains;
(g) removing the first and second insulating films by performing etching so that upper ends of the first and second insulating films are lower than upper ends of the lower electrode and the trench electrode after removing the resist mask;
(h) forming a third insulating film on a side wall of the first trench and an upper portion of the lower electrode and forming a fourth insulating film on a side wall of the second trench and an upper portion of the trench electrode;
(i) embedding the conductor in the first and second trenches in a state where the third and fourth insulating films are formed, forming an upper electrode including a pointed portion in the first trench, and embedding a viewing member in the second trench;
(j) removing the conductor and the third and fourth insulating films on the main surface;
(k) observing the trench electrode from a side of the main surface, acquiring a positional relationship among the trench electrode, the viewing member, and the second insulating film, and estimating and managing a width and a shape of the pointed portion of the first trench; and
(l) forming an interlayer insulating film above the first and second trenches in a case where the estimated width and shape of the pointed portion are within a range of design.
